(19) United States
(12) Patent Application Publication
(10) Pub. No.: US 2025/0248146 A1
(43) Pub. Date: Jul. 31, 2025

(54) IMAGE SENSING DEVICE

(71) Applicant: SK hynix Inc., Icheon-si (KR)

(72) Inventors: Hyun Soo LIM, Icheon-si (KR); Sung Ho CHOI, Icheon-si (KR)

(21) Appl. No.: 18/777,962

(22) Filed: Jul. 19, 2024

(30) Foreign Application Priority Data
Jan. 26, 2024 (KR) 10-2024-0012480

(51) Int. Cl. H01L 27/146

(52) U.S. Cl. CPC H10F 39/8023; H10F 39/182; H10F 39/8037; H10F 39/8053; H10F 39/8063; H10F 39/807; H10F 39/026; H10F 39/809

(57) ABSTRACT

Image sensing devices are disclosed. In an embodiment, an image sensing device includes a plurality of pixels, each of which includes at least one sub-pixel. The sub-pixel may include a photodiode, a transfer transistor and a plurality of pixel transistors. The transfer transistor may transfer a charge generated in the photodiode to a diffusion region. The plurality of the pixel transistors may generate a pixel signal based on the charge received from the transfer transistor. The transfer transistor is positioned closer to a center of the sub-pixel than each of the plurality of the pixel transistors.

### CROSS-REFERENCES TO RELATED APPLICATION

This patent document claims the priority and benefits of Korean application number 10-2024-0012480, filed on Jan. 26, 2024, which is incorporated herein by reference in its entirety.

### TECHNICAL FIELD

The technology and implementations disclosed in this patent document generally relate to an image sensing device.

### BACKGROUND

An image sensing device may include a pixel array and a control logic. The pixel array may include a plurality of pixels. Each of the pixels may include a photodiode that receives light and generates electrical signals based on the light received. The control logic may control operations related to the pixel array. Further, the control logic may receive a pixel signal provided from the pixel to generate image data.

To meet high resolution and high sensitivity characteristics, such an image sensing device is required to secure high transconductance and conversion gain.

### SUMMARY

Example embodiments provide an image sensing device that may be capable of improving charge transfer efficiency.

In some example embodiments, an image sensing device may include a plurality of pixels. Each of the pixels may include at least one sub-pixel. The sub-pixel may include a photodiode, a transfer transistor and a plurality of pixel transistors. The transfer transistor may transfer charges generated in the photodiode to a diffusion region. The plurality of the pixel transistors may generate a pixel signal based on the charges received from the transfer transistor.

In some example embodiments, an image sensing device may include a first sub-pixel group and a second sub-pixel group. The first sub-pixel group may include a first sub-pixel and a second sub-pixel. The first sub-pixel and the second sub-pixel in the first sub-pixel group may be arranged side by side along a first direction. The second sub-pixel group and the first sub-pixel group may be arranged side by side along a second direction substantially perpendicular to the first direction. The second sub-pixel group may include a first sub-pixel and a second sub-pixel. The first sub-pixel and the second sub-pixel in the second sub-pixel group may be arranged side by side along the first direction. Each of the first sub-pixels and the second sub-pixels in the first and second sub-pixel groups may include a first active region, a second active region and a third active region. The first active region may be arranged in a first region of each of the first and second sub-pixels (e.g., an upper region on a plan view). The second active region may be arranged in a central region of each of the first and second sub-pixels on the plan view. The third active region may be arranged in a second region on the plan view. The second region is on an opposite side of the central region from the first region. Each of the first and second sub-pixels may include a photodiode, a first pixel transistor, a second pixel transistor and a transfer transistor. The photodiode may be arranged to at least partially overlap the first to third active regions. The first pixel transistor may be disposed in at least one of the first active region and the third active region. The second pixel transistor may be disposed in a remaining one of the first active region and the third active region. The transfer transistor may include a floating diffusion region disposed in the second active region.

In some example embodiments, the one of the first and second pixel transistors may include a reset transistor, a selection transistor, a first dual conversion gain transistor and a second dual conversion gain transistor. The remaining one of the first and second pixel transistors may include a driving transistor.

In some example embodiments, an image sensing device may include a semiconductor substrate, a pixel isolation layer, a photodiode, a device isolation layer, a pixel transistor and a transfer transistor. The semiconductor substrate may have a first conductive type. The semiconductor substrate may include a front side and a back side. The pixel isolation layer may be formed in the semiconductor substrate to define a first pixel and a second pixel. Each of the first and second pixels may include a first sub-pixel and a second sub-pixel. The photodiode may be formed in the semiconductor substrate defined by the first and second sub-pixels. The photodiode may have a second conductive type. The device isolation layer may be formed on the front side of the semiconductor substrate defined by the first and second sub-pixels to define a first active region, a second active region and a third active region. The pixel transistor may be arranged in at least one of the first active region and the third active region. The transfer transistor may include a floating diffusion region arranged in the second active region. The second active region may be positioned between the first active region and the third active region.

In some example embodiments, the image sensing device may include the transfer transistor and the floating diffusion region arranged in the central region of the photodiode, e.g., a central portion of the sub-pixel.

Thus, a distance between the transfer transistor and edge regions of the photodiode may be decreased. Further, a uniform distance between the edge regions of the photodiode and the transfer transistor can improve a charge transfer characteristic. Therefore, by improving the charge transfer characteristic, more charges can be transferred by applying a small power voltage, thereby improving a lag characteristic. As a result, a transconductance (Gm) characteristic may be improved, a conversion gain may also be secured, and a noise may be improved.

In some example embodiments, the transfer transistor may be arranged at each of the central regions of the sub-pixels so that the pixel transistors may be formed in the first region (e.g., upper region on the plan view) and the second region (e.g., lower region on the plan view) of each of the sub-pixels. Thus, a TCG pixel circuit requiring at least five pixel transistors may be formed by only the tow pixels including the four sub-pixels. As a result, the pixel circuit may include the pixels less than the pixels in the conventional pixel circuit.

In some example embodiments, the pixel transistors may be formed in the first region and the second region of each of the sub-pixels so that the driving transistor may be arranged at each of the sub-pixels in the shape of fingers to improve an output property of the driving transistor.

In some example embodiments, there may be provided an image sensing device. The image sensing device may include a plurality of pixels. Each of the pixels may include at least one sub-pixel. The sub-pixel may include a photo diode, a transfer transistor and a plurality of pixel transistors. The transfer transistor may transfer charges, which may be generated from the photo diode, to a diffusion region. The plurality of the pixel transistors may generate a pixel signal based on the charges provided from the transfer transistor.

In some example embodiments, there may be provided an image sensing device. The image sensing device may include a first pixel and a second pixel. The first pixel may include a first sub-pixel and a second sub-pixel. The first sub-pixel and the second sub-pixel in the first pixel may be arranged in side by side along a first direction. The second pixel and the first pixel may be arranged side by side along a second direction substantially perpendicular to the first direction. The second pixel may include a first sub-pixel and a second sub-pixel. The first sub-pixel and the second sub-pixel in the second pixel may be arranged side by side along the first direction. Each of the first sub-pixels and the second sub-pixels in the first and second sub-pixels may include a first active region, a second active region and a third active region. The first active region may be arranged in an upper region on a planar view. The second active region may be arranged in a central region on the planar view. The third active region may be arranged in a lower region on the planar view. Each of the first and second sub-pixels may include a photo diode, a first pixel transistor, a second pixel transistor and a transfer transistor. The photo diode may be overlapped with the first to third active regions. The first pixel transistor may be integrated in at least one of the first active region and the third active region. The second pixel transistor may be integrated in a remaining one of the first active region and the third active region. The transfer transistor may include a floating diffusion region integrated in the second active region.

In some example embodiments, any one of the first and second pixel transistors may include a reset transistor, a selection transistor, a first dual conversion gain transistor and a second dual conversion gain transistor. A remaining one of the first and second pixel transistors may include a drive transistor.

In some example embodiments, there may be provided an image sensing device. The image sensing device may include a semiconductor substrate, a pixel isolation layer, a photo diode, a device isolation layer, a pixel transistor and a transfer transistor. The semiconductor substrate may have a first conductive type. The semiconductor substrate may include an upper surface and a back side. The pixel isolation layer may be formed in the semiconductor substrate to define a first pixel and a second pixel. Each of the first and second pixels may include a first sub-pixel and a second sub-pixel. The photo diode may be formed in the semiconductor substrate defined by the first and second sub-pixels. The photo diode may have a second conductive type. The device isolation layer may be formed on the upper surface of the semiconductor substrate defined by the first and second sub-pixels to define a first active region, a second active region and a third active region. The pixel transistor may be arranged in at least one of the first active region and the third active region. The transfer transistor may include a floating diffusion region arranged in the second active region. The second active region may be positioned between the first active region and the third active region.

In some example embodiments, the image sensing device may include the transfer transistor and the floating diffusion region which are arranged in the central region of the photo diode, i.e., a central portion of the sub-pixel.

Thus, a distance between the transfer transistor and edge regions of the photo diode may be decreased. Further, a uniform distance may be provided between the edge regions of the photo diode and the transfer transistor to improve a charge transfer characteristic. Therefore, by improving the charge transfer characteristic, great charges may be transferred by applying a small power voltage to improve a lag characteristic. As a result, a transconductance (Gm) characteristic may be improved, a conversion gain may also be secured and a noise may be improved.

In some example embodiments, the transfer transistor may be arranged at each of the central regions of the sub-pixels so that a space where the pixel transistors may be integrated may be formed in the upper region and the lower region of each of the sub-pixels. Thus, a TCG pixel circuit requiring at least five pixel transistors may be formed by only the tow pixels including the four sub-pixels. As a result, the pixel circuit may include the pixels less than the pixels in the conventional pixel circuit.

In some example embodiments, the space where the pixel transistors may be integrated may be formed in the upper region and the lower region of each of the sub-pixels so that the drive transistor may be arranged at each of the sub-pixels in a shape of fingers to improve an output property of the drive transistor.

### BRIEF DESCRIPTION OF THE DRAWINGS

The above and another aspects, features and advantages of the subject matter of the present disclosure will be more clearly understood from the following detailed description taken in conjunction with the accompanying drawings.

FIG. 1 is a block diagram illustrating an image sensing system based on some example embodiments.

FIG. 2 is a cross-sectional view illustrating a pixel based on some example embodiments.

FIG. 3 is a circuit diagram illustrating a pixel circuit based on some example embodiments.

FIG. 4 is a plan view illustrating a unit pixel based on some example embodiments.

FIG. 5A is a cross-sectional view taken along a line A-A′ in FIG. 4.

FIG. 5B is a cross-sectional view taken along a line B-B′ in FIG. 4.

FIG. 5C is a cross-sectional view taken along a line C-C′ in FIG. 4.

FIG. 6 is a block diagram illustrating an image sensing device based on some example embodiments.

FIG. 7 is a plan view illustrating the image sensing device including a first pixel circuit in FIG. 6.

FIG. 8 is a circuit diagram illustrating a portion “D in FIG. 6;

FIG. 9 is a graph showing characteristics of a driving transistor based on some example embodiments.

FIG. 10 is a graph showing charges flow between a photodiode and a floating diffusion region based on some example embodiments.

FIG. 11 is a perspective view illustrating an image sensing module based on some example embodiments.

### DETAILED DESCRIPTION

In some embodiments discussed in this patent document, the term “configured” can be used to indicate a size, shape, material composition, orientation, and/or arrangement of a structure and/or an apparatus that facilitates the operation of one or more of the structure and the apparatus in a pre-determined way.

In some embodiments discussed in this patent document, the terms “vertical,” “longitudinal,” “horizontal,” and “lateral” can be used differently depending on the reference point of a structure. For example, a “horizontal” or “lateral” direction is a direction that is substantially parallel to a major plane of the structure, while a “vertical” or “longitudinal” direction is a direction that is substantially perpendicular to the major plane of the structure. In some embodiments, the major plane of the structure is defined by a surface of the structure having a relatively large area compared to other surfaces of the structure. With reference to the figures, a “horizontal” or “lateral” direction may be perpendicular to Z-axis, and may be parallel to X-axis and/or parallel to Y-axis; and a “vertical” or “longitudinal” direction may be parallel to Z-axis, may be perpendicular to X-axis, and may be perpendicular to Y-axis.

In some embodiments discussed in this patent document, spatially relative terms, such as “beneath,” “below,” “bottom,” “bottom,” “above,” “upper,” “top,” “front,” “rear,” “left,” “right,” etc., may be used to facilitate the description of the relationship between different elements or the relationship between different features as illustrated in the figures. In some embodiments, the spatially relative terms can be used to encompass different orientations of structures in addition to the orientation depicted in the figures. For example, if structures in the figures are inverted, the corresponding structures described as disposed “below” or “beneath” or “under” or “on bottom of” other structures can be disposed “above” or “on top of” the other structures.

In some example embodiments discussed in this patent document, the expression “upper region” can be used to indicate a region adjacent to a previous row or a previous column on the same plane, or a region located above a reference position on the same plane. In some example embodiments discussed in this patent document, the expression “lower region” can be used to indicate a region adjacent to a subsequent row or a subsequent column on the same plane, or a region located below the reference position on the same plane.

In some embodiments discussed in this patent document, the phrases “coupled to” and “connected to” can be used to refer to both direct and indirect connections, such as electrical connections through a direct Ohmic connection or through another structure.

The disclosed technology can be implemented in some embodiments to provide an image sensing device with an array of pixels for detecting light. Each pixel includes one or more sub-pixels and each sub-pixel includes a photodetector for detecting incident light to generate electrical charge representing the detected incident light. Such a photodetector may be implemented in various configurations, including, for example, a photodiode, a phototransistor, or a photogate.

In implementation, a transfer transistor and a floating diffusion region may be arranged at a central region of a photodetector such as a photodiode to improve charge transfer efficiency. In some embodiments, the central region may include a center (or a center point) of a sub-pixel.

By arranging the transfer transistor and the floating diffusion region at the central region of a photodiode, the distance that charges travel from the edges of the photodiode is reduced, thereby improving charge transfer efficiency.

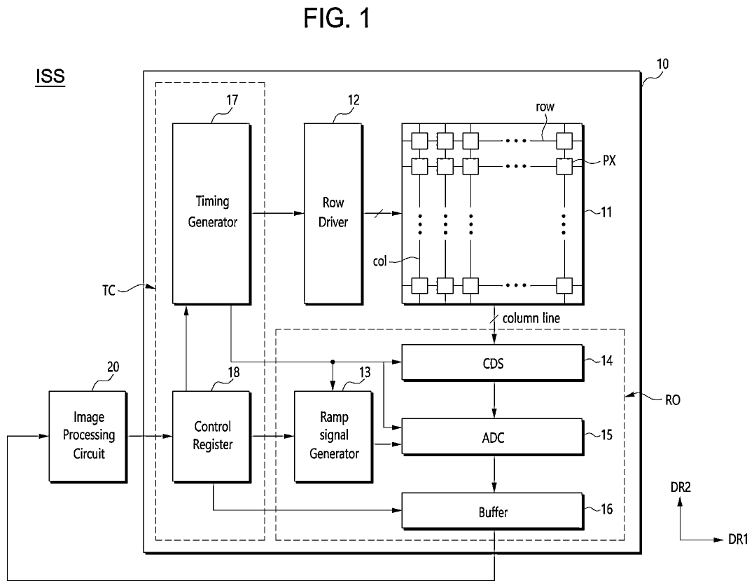

FIG. 1 is a block diagram illustrating an image sensing system based on some example embodiments.

Referring to FIG. 1, an image sensing system ISS of example embodiments may include an image sensing device 10 and an image processing circuit 20.

The image sensing device 10 may convert a received light into an electrical signal to generate image data. The image sensing device 10 may include a pixel array 11, a row driver 12, a readout circuit RO and a timing controller TC.

The pixel array 11 may include a plurality of pixels PX. Each of the pixels PX may include at least one photodiode configured to convert the received light into a charge (or charges). The pixel array 11 may include a plurality of row lines row and a plurality of column lines col. For example, the row lines row may be extended in a first direction DR1 in parallel. The column lines col may be extended in a second direction DR2 in parallel. The first direction DR1 and the second direction DR2 may be substantially perpendicular to each other. The pixels PX may be electrically coupled between the row lines row and the column lines col, respectively. For example, each of the pixels PX may include at least two photodiodes. At least one pixel PX may include a pixel circuit configured to generate a pixel signal. The pixel signal may correspond to charges generated by at least one photodiode which arranged at the at least one pixel PX. Further, the at least one of the pixels PX may provide an auto focus function.

The row driver 12 may drive the pixel array 11 per each row line row. For example, the image sensing device 10 may include a plurality of row drivers 12 corresponding to the plurality of row lines row. The plurality of row drivers 12 may output a plurality driving signals for driving the pixel circuits to the plurality of row lines row. For example, the plurality of row driver 12 may sequentially provide the plurality of row lines row.

The readout circuit RO may include a ramp signal generator 13, a sampling circuit 14, an analog-to-digital converter (ADC) 15 and a buffer 16.

The sampling circuit 14 may include a plurality of samplers (not shown). The plurality of samplers may be connected with the plurality of pixels PX through the plurality of column lines col, respectively. For example, each of the plurality of samplers may include a correlated double sampler (CDS). Each of the samplers may detect a difference between a reset voltage and a pixel voltage of the pixels PX connected to a selected row line. Each of the samplers may output the difference as an analog signal.

The ADC 15 may compare the analog signal provided from the sampling circuit 14 with a ramp voltage. The ramp voltage may be generated from the ramp signal generator 13. The ADC 15 may convert the comparison result into a digital signal. The ADC 15 may output the digital signal as the image data. For example, the image data may be proportional to an amount of the received light.

The buffer 16 may receive the image data. The buffer 16 may temporarily store the image data. The buffer 16 may sequentially provide the image processing circuit 20 with the image data.

The timing controller TC may control the row driver 12 and the readout circuit RO. The timing controller TC may include a timing generator 17 and a control register 18.

The timing generator 17 may generate a timing signal for controlling the row driver 12, the ramp signal generator 13, the sampling circuit 14 and the ADC 15. The ramp signal generator 13 may generate the ramp voltage for controlling the image data in the buffer 16 based on the timing signal of the timing generator 17.

The control register 18 may generate various control signals for controlling the ramp signal generator 13, the buffer 16 and the timing generator 17. Thus, the ramp signal generator 13, the buffer 16 and the timing generator 17 may be individually controlled by the control signals.

The image processing circuit 20 may generate an image based on the image data transferred from the buffer 16. The image processing circuit 20 may process the image data. The image processing circuit 20 may output the processed image data as the image. In some example embodiments, the image processing circuit 20 may interpolate the image data corresponding to the pixel signals of the pixels PX. The image processing circuit 20 may generate the interpolated image data.

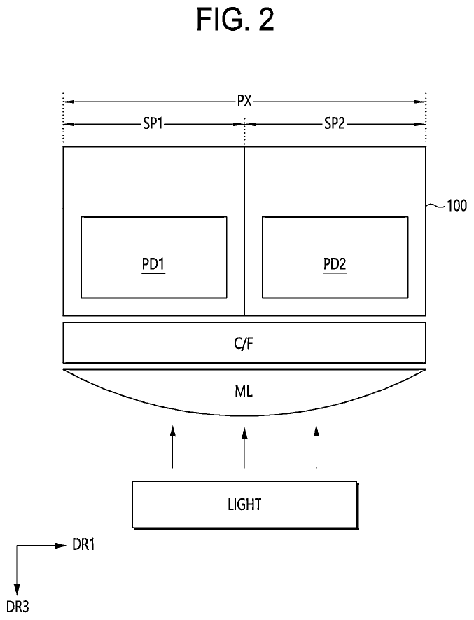

FIG. 2 is a cross-sectional view illustrating a pixel based on example embodiments.

Referring to FIGS. 1 and 2, the pixel PX of example embodiments may include a first photodiode PD1 and a second photodiode PD2. The pixel PX may correspond to a color filter C/F and a micro-lens ML. For example, the color filter C/F may be arranged on a back side of a semiconductor substrate 100 to cover the first photodiode PD1 and the second photodiode PD2. For example, the back side of the semiconductor substrate 100 may be a surface to which a light may be incident. The first photodiode PD1 and the second photodiode PD2 may be formed adjacent to the back side of the semiconductor substrate 100. The color filter C/F and the micro-lens ML may be sequentially stacked on the back side of the semiconductor substrate 100. In some example embodiments, a region where the first photodiode PD1 may be formed may be referred to as a first sub-pixel SP1. A region where the second photodiode PD2 may be formed may be referred to as a second sub-pixel SP2.

A pixel isolation layer (not shown) may be formed between the pixels PX and/or between the first sub-pixel SP1 and the second sub-pixel SP2 to prevent the charges from being transferred.

For example, the first sub-pixel SP1 and the second sub-pixel SP2 may be arranged adjacent to each other along the first direction DR1. The color filter C/F and the micro-lens ML may be stacked on the back side of the semiconductor substrate 100 along a third direction DR3 substantially perpendicular to the first direction DR1 and the second direction DR2.

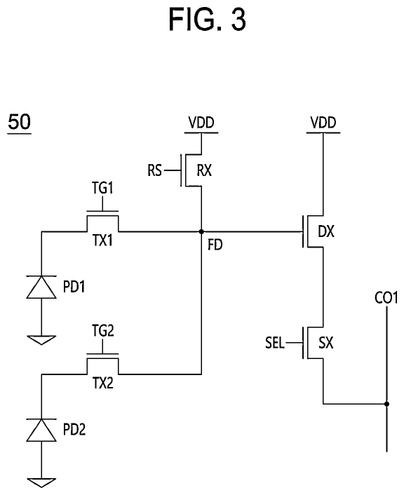

FIG. 3 is a circuit diagram illustrating a pixel circuit based on example embodiments.

Referring to FIGS. 1 to 3, a pixel circuit 50 may include a floating diffusion region FD, a first transfer transistor TX1, a second transfer transistor TX2, a reset transistor TX, a driving transistor DX and a selection transistor SX. The reset transistor RX, the driving transistor DX and the selection transistor SX may generate pixel signals based on the charges transferred from the first transfer transistor TX1 and/or the second transfer transistor TX2.

The first transfer transistor TX1 may be connected between the first photodiode PD1 and the floating diffusion region FD. The second transfer transistor TX2 may be connected between the second photodiode PD2 and the floating diffusion region FD. The first transfer transistor TX1 may transfer charges generated from the first photodiode PD1 to the floating diffusion region FD based on a first transfer gate signal TG1. The second transfer transistor TX2 may transfer charges generated from the second photodiode PD2 to the floating diffusion region FD based on a second transfer gate signal TG2.

The reset transistor RX may be electrically coupled between a power voltage terminal VDD and the floating diffusion region FD. The reset transistor RX may provide the floating diffusion region FD with a power voltage VDD based on a reset control signal RS. The driving transistor DX may be electrically coupled between the power voltage terminal VDD and the selection transistor SX. The driving transistor DX may be turned-on based on a voltage of the floating diffusion region FD. The voltage of the floating diffusion region FD may be changed based on the charges transferred to the floating diffusion region FD. The selection transistor SX may be connected between the driving transistor DX and the column line col. The selection transistor SX may provide the column line col with an output voltage of the driving transistor DX as the pixel signal (or the pixel voltage) based on a selection control signal SEL.

The pixel circuit 50 may be driven by following processes.

When the reset transistor RX may be turned-on, the voltage of the floating diffusion region FD may be reset to the power voltage VDD. When the selection control signal SEL may be enabled after resetting the floating diffusion region FD, the selection transistor SX may be turned-on to output a reset voltage, i.e., the power voltage VDD to the column line col.

When the first transfer transistor TX1 may be turned-on after resetting the column line col, the charges generated from the first photodiode PD1 may be transferred to the floating diffusion region FD.

The driving transistor DX may be turned-on based on the quantity of the charges in the floating diffusion region FD. Thus, the driving transistor DX may be operated as a source follower amplifier configured to amplify the voltage based on the quantity of the charges in the floating diffusion region FD.

When the selection transistor SX may be turned-on by the selection control signal SEL, the output voltage of the driving transistor DX may be transferred to the column line col. The output voltage of the driving transistor DX may be a first pixel signal corresponding to the charges generated from the first photodiode PD1.

When the second transfer transistor TX2 may be turned-on after outputting the first pixel signal to the column line col, the charges generated from the second photodiode PD2 may be transferred to the floating diffusion region FD. The driving transistor DX and the selection transistor SX may be driven based on the charges generated from the second photodiode PD2 similarly to the output of the first pixel voltage to output a second pixel signal corresponding to the charges of the second photodiode PD2 to the column line col.

The first transfer gate signal TG1, the second transfer gate signal TG2, the reset control signal RS and the selection control signal SEL may be the driving signals outputted from the row driver 12.

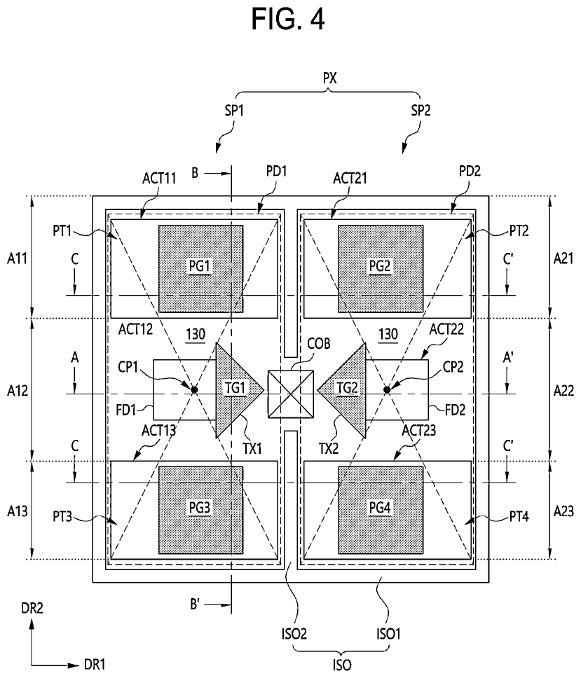

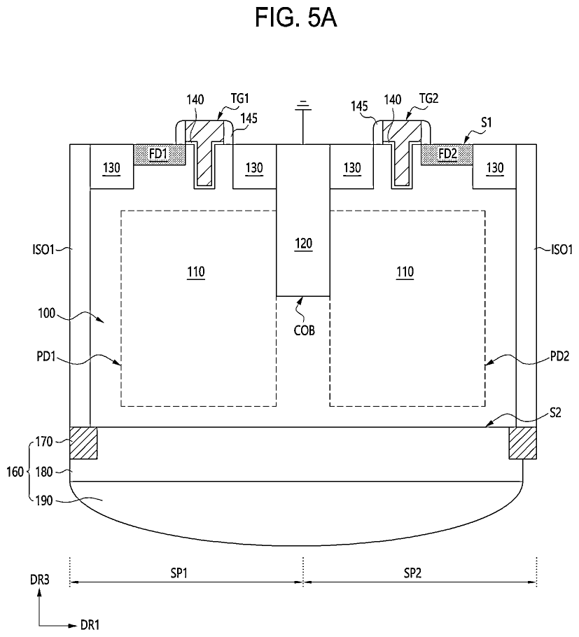

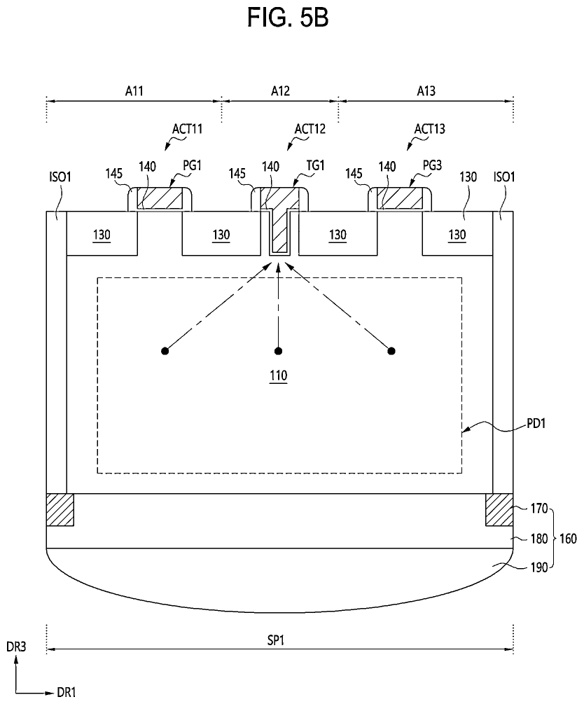

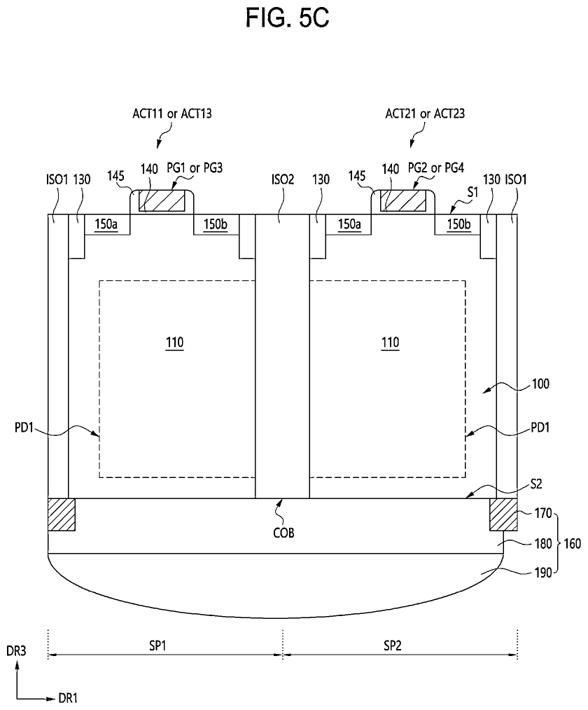

FIG. 4 is a plan view illustrating a unit pixel based on example embodiments, FIG. 5A is a cross-sectional view taken along a line A-A′ in FIG. 4, FIG. 5B is a cross-sectional view taken along a line B-B′ in FIG. 4 and FIG. 5C is a cross-sectional view taken along a line C-C′ in FIG. 4.

Referring to FIGS. 4, 5A, 5B and 5C, the semiconductor substrate 100 may have a first surface S1 and a second surface S2. The first surface S1 and the second surface S2 may be opposite to each other by a thickness of the semiconductor substrate 100. The first surface S1 may be a front side of the semiconductor substrate 100. The second surface S2 may be a back side of the semiconductor substrate 100. The semiconductor substrate 100 may include a first conductive type silicon substrate. For example, the first conductive type may include p type impurities. Alternatively, the semiconductor substrate 100 may be a substrate including a first conductive type well, or a first conductive type epitaxial layer.

A pixel isolation layer ISO may be formed in the semiconductor substrate 100 to define the pixel PX including the first sub-pixel SP1 and the second sub-pixel SP2. For example, the pixel isolation layer ISO may include a first pixel isolation layer ISO1 and a second pixel isolation layer ISO2. The first pixel isolation layer ISO1 may be an inter pixel isolation layer configured to isolate the pixels PX from each other. The second pixel isolation layer ISO2 may be an in-pixel isolation layer arranged in the first pixel isolation layer ISO1 to define the first sub-pixel SP1 and the second sub-pixel SP2. The first pixel isolation layer ISO1 and the second pixel isolation layer ISO2 may have a same deep trench isolation (DTI) structure or different DTI structures.

For example, at least one of the first and second pixel isolation layers ISO1 and ISO2 may be formed in a deep trench formed through the semiconductor substrate 100. The deep trench may be extended from the first surface S1 to the second surface S2 or from the first surface S1 to a point spaced apart from the second surface S2 in the semiconductor substrate 100.

At least one of the first and second pixel isolation layers ISO1 and ISO2 may include at least one insulation material in the deep trench. The insulation material may have a refractive index lower than a refractive index of the semiconductor substrate 100. Alternatively, at least one of the first and second pixel isolation layers ISO1 and ISO2 may include at least one of a silicon oxide layer, a silicon nitride layer, an undoped polysilicon layer and air. Further, at least one of the first and second pixel isolation layers ISO1 and ISO2 may include an insulation liner formed along an inner surface of the deep trench, a polysilicon layer with conductive impurities on the insulation liner to fill up the deep trench, and an insulation capping layer. At least one of the first and second pixel isolation layers ISO1 and ISO2 may include a front deep trench isolation (FDTI) extended from the first surface S1 to the second surface S2, but not limited thereto. When the first and second pixel isolation layers ISO1 and ISO2 may include the FDTI, the first and second pixel isolation layers ISO1 and ISO2 may have gradually decreased widths toward the second surface S2. At least one of the first and second pixel isolation layers ISO1 and ISO2 may include a back deep trench isolation (BDTI) extended from the second surface S2 to the first surface S1. When the first pixel isolation layer ISO1 or the second pixel isolation layer ISO2 may include the BDTI, the first pixel isolation ISO1 or the second pixel isolation layer ISO2 may have gradually decreased widths toward the first surface S1.

On a plan view, the second pixel isolation layer ISO2 may be extended in the second direction DR2. Thus, the first and second sub-pixels SP1 and SP2 may be arranged at both sides of the second pixel isolation layer ISO2. Further, the first and second sub-pixels SP1 and SP2 may be arranged side by side in the first direction DR1. The second pixel isolation layer ISO2 may physically reflect lights incident on border portions between the first photodiode PD1 and the second photodiode PD2. A crosstalk in the border portions between the first and second photodiodes PD1 and PD2 may be reduced by the second pixel isolation layer ISO2.

The first and second pixel isolation layers ISO1 and ISO2 may prevent the charges generated by the light incident to the first and second sub-pixels SP1 and SP2 from flowing into the adjacent pixel PX or the sub-pixel by a random drift.

On the plan view, the first sub-pixel SP1 may include an upper region A11, a central region A12 and a lower region A13 based on a center point CP1 (hereinafter, first center point) of the first sub-pixel SP1, along the second direction DR2. The second sub-pixel SP2 may include an upper region A21, a central region A22 and a lower region A23 based on a center point CP2 (hereinafter, second center point) of the second sub-pixel SP2, along the second direction DR2. For example, the central region A12 may include the first center point CP1 and the central region A22 may include the second center point CP2.

For example, when the first sub-pixel SP1 may have a quadrangular shape, the first center point CP1 may be an intersected point between diagonal lines of the first sub-pixel SP1. When the second sub-pixel SP2 may have a quadrangular shape, the second center point CP2 may be an intersected point between diagonal lines of the second sub-pixel SP2. For example, the upper regions A11 and A21 may be positioned adjacent to a pixel connected to a previous row line. The lower regions A13 and A23 may be positioned adjacent to a pixel connected to a next row line.

The first photodiode PD1 may be formed through the upper region A11, the central region A12 and the lower region A13 of the first sub-pixel SP1. For example, the first photodiode PD1 may be formed in the semiconductor substrate 100 corresponding to the upper region A11, the central region A12 and the lower region A13.

The second photodiode PD2 may be formed through the upper region A21, the central region A22 and the lower region A23 of the second sub-pixel SP2. For example, the second photodiode PD2 may be formed in the semiconductor substrate 100 corresponding to the upper region A21, the central region A22 and the lower region A23.

The first and second photodiodes PD1 and PD2 may include a second conductive type impurity region 110 formed in the semiconductor substrate 100 having a first conductive type. The second conductive type impurities may be opposite to the first conductive type. For example, the second conductive type impurities may include n type impurities. The second conductive type impurity region 110 and the first conductive type semiconductor substrate 100 may form a PN junction to form the first and second photodiodes PD1 and PD2. The first and second photodiodes PD1 and PD2 may be formed closer to the second surface S2 than the first surface S1. The first and second photodiodes PD1 and PD2 may have substantially the same size or different sizes.

A charge overflow barrier (COB) may be formed between the first sub-pixel SP1 and the second sub-pixel SP2, particularly, the first photodiode PD1 and the second photodiode PD2. The COB may control a potential barrier between the first and second photodiodes PD1 and PD2 to allow the charge transfer between the first and second photodiodes PD1 and PD2. For example, the COB may be positioned in the second pixel isolation layer ISO2. As shown in FIG. 5A, the COB may be a second conductive type impurity region 120 arranged between the first and second photodiodes PD1 and PD2, but not limited thereto. Alternatively, the COB may have various shapes configured to receive a ground voltage.

Each of the first and second sub-pixels SP1 and SP2 may further include a device isolation layer 130 configured to define active regions. The device isolation layer 130 may have a shallow trench isolation (STI) structure having a depth shallower than depths of the first and second pixel isolation layers ISO1 and ISO2. For example, the device isolation layer 130 may be formed in a shallow trench extended from the first surface S1 of the semiconductor substrate 100 to a position spaced apart from the first and second photodiodes PD1 and PD2. The device isolation layer 130 may include at least one insulation material in the shallow trench. The device isolation layer 130 may provide the active regions where various devices in the pixels may be integrated.

The first sub-pixel SP1 may include a first active region ACT11, a second active region ACT12 and a third active region ACT13. The second sub-pixel SP2 may include a first active region ACT 21 a second active region ACT22 and a third active region ACT23.

The first active regions ACT11 and ACT21 may be positioned in the upper regions A11 and A21 of the first and second sub-pixels SP1 and SP2. The second active regions ACT12 and ACT22 may be positioned in the central regions A12 and A22 of the first and second sub-pixels SP1 and SP2. The third active regions ACT13 and ACT33 may be positioned in the lower regions A13 and A23 of the first and second sub-pixels SP1 and SP2.

In some example embodiments, pixel transistors PT1, PT2, PT3 and PT4 of the pixel circuit 50 in FIG. 3 may be integrated in each of the first active regions ACT11 and ACT21 and the third active regions ACT13 and ACT23. For example, the pixel transistors PT1, PT2, PT3 and PT4 may include at least one of the reset transistor RX, the selection transistor SX and the driving transistor DX. In some example embodiments, the first pixel transistor PT1 may be the reset transistor RX. The second pixel transistor PT2 may be the selection transistor SX. The third and fourth transistors PT3 and PT4 may be the driving transistor DX. Alternatively, at least one of the pixel transistors PT1, PT2, PT3 and PT4 may be divided into a plurality of sub transistors according to a gate fingering manner. Reference numerals PG1, PG2, PG3 and PG4 may indicate pixel gates of the first to fourth transistors PT1, PT2, PT3 and PT4. Impurity regions 150a and 150b including second conductive type impurities may be formed in the first and third active regions ACT11, ACT21, ACT13, and ACT23 at both sides of the first to fourth pixel gates PG1, PG2, PG3 and PG4. The first to fourth pixel gates PG1, PG2, PG3 and PG4 may have a planar structure, but not limited thereto.

The first transfer transistor TX1 and the first floating diffusion region FD1 may be integrated in the central region A12 of the first sub-pixel SP1. The second transfer transistor TX2 and the second floating diffusion region FD2 may be integrated in the central region A22 of the second sub-pixel SP2.

In some example embodiments, the first transfer gate TG1 of the first transfer transistor TX1 may be arranged on the second active region ACT12. As shown in FIG. 5A, the first transfer gate TG1 may have a recess gate structure, but not limited thereto. A gate insulation layer 140 may be interposed between the first transfer gate TG1 and the semiconductor substrate 100. An insulation spacer 145 may be formed on both sidewalls of the first transfer gate TG1.

Second conductive type impurities may be implanted into the second active region ACT12 exposed by the first transfer gate TG1 to form the first floating diffusion region FD1.

In FIG. 3, the first transfer transistor TX1, the first photodiode PD1 and the first floating diffusion region FD1 may be depicted as separated elements, but not limited thereto. For example, the first photodiode PD1 may be operated as a source of the first transfer transistor TX1. The first floating diffusion region FD1 may be operated as a drain of the first transfer transistor TX1.

The second transfer gate TG2 of the second transfer transistor TX2 may be arranged on the second active region ACT22. The second transfer gate TG2 may have the recess gate structure substantially the same as the recess gate structure of the first transfer gate TG1. The second transfer gate TG2 may be symmetrical with the first transfer gate TG1 with respect to the second pixel isolation layer ISO2.

Second conductive type impurities may be implanted into the second active region ACT22 exposed by the second transfer gate TG2 to form the second floating diffusion region FD2. Thus, the second transfer transistor TX2 may be integrated in the central region A22 of the second sub-pixel SP2. The second photodiode PD2 may be operated as a source of the second transfer transistor TX2. The second floating diffusion region FD2 may be operated as a drain of the second transfer transistor TX2.

The second active regions ACT12 and ACT22 may be arranged in the central regions A12 and A22 of the first and second sub-pixels SP1 and SP2. For example, the first transfer gate TG1 may be positioned at one side (for example, a right side of the first center point CP1) of the second active region ACT12. The second transfer gate TG2 may be positioned at the other side (for example, a left side of the second center point CP2) of the second active region ACT 22. For example, the first and second transfer gates TG1 and TG2 may be symmetrical with each other with respect to the second pixel isolation layer ISO2. Thus, the first transfer gate TG1 in the first sub-pixel SP1 may be positioned closer to the first center point CP1 than the first and third pixel gates PG1 and PG3 in the first sub-pixel SP1. Similarly, the second transfer gate TG2 in the second sub-pixel SP2 may be positioned closer to the second center point CP2 than the second and fourth pixel gates PG2 and PG4 in the second sub-pixel SP2.

As a result, the first transfer transistor TX1 in the first sub-pixel SP1 may be positioned closer to the first center point CP1 than the first and third pixel transistors PT1 and PT3 in the first sub-pixel SP1. Similarly, the second transfer transistor TX2 in the second sub-pixel SP2 may be positioned closer to the second center point CP2 than the second and fourth pixel transistors PT2 and PT4 in the second sub-pixel SP2.

Generally, the charge transfer efficiency of the image sensing device 10 may be based on a ratio of the charges transferred to the floating diffusion region FD1 or FD2 with respect to the charge generated from the photodiode PD1 or PD2.

Since the transfer transistors TX1 and TX2 including the floating diffusion regions FD1 and FD2 may be arranged in the central regions A12 and A22 of the sub-pixels SP1 and SP2 where the photodiodes PD1 and PD2 are formed, distances between the transfer transistors TX1 and T2 and edge portions of the photodiodes PD1 and PD2 may be reduced. That is, by arranging the transfer transistors TX1 and TX2 including the floating diffusion regions FD1 and FD2 in the central regions A12 and A22, as shown in FIG. 5B, a distance between the photodiodes PD1 and PD2 positioned in the upper regions A11 and A21 and the transfer transistors TX1 and TX2, and a distance between the photodiodes PD1 and PD2 positioned in the lower regions A13 and A23 and the transfer transistors TX1 and TX2 as well as the distance between the photodiodes PD1 and PD2 positioned in the central regions A12 and A22 and the transfer transistors TX1 and TX2 may also be decreased. Therefore, the distances between the transfer transistors TX1 and TX2 and a whole region of the photodiodes PD1 and PD2 may be decreased to improve the transfer efficiency of the charges generated from the photodiodes PD1 and PD2.

A reference numeral 120 may be the second conductive type impurity region for forming the COB. For example, the COB may be connected to a ground voltage. As shown in FIG. 3, the first and second floating diffusion regions FD1 and FD2, the first to fourth pixel transistors PT1 to PT4 and the first and second transfer transistors TX1 and TX2 may be electrically connected with each other by a multi interconnection lines (not shown) over the first surface S1 of the semiconductor substrate 100. The multi interconnection lines may have a multi-level conductive lines. The multi interconnection lines may be connected to an uppermost bonding pad (not shown). A node FD in FIG. 3 may indicate the first and second floating diffusion regions FD1 and FD2 which are electrically coupled each other, in FIG. 4.

An optical layer 160 may be arranged over the second surface S2 of the semiconductor substrate 100. The optical layer 160 may include a grid structure 170, a color filter 180 and a micro-lens 190. The optical layer 160 may condense and filter an incident light. The optical layer 160 may provide the first and second photodiodes PD1 and PD2 with the light.

The grid structure 170 may be arranged on the second surface S2 of the semiconductor substrate 100. For example, the grid structure 170 may have a structure corresponding to the structure of the first pixel isolation layer ISO1. A width of the grid structure 170 may be narrower than a width of the first pixel isolation layer ISO1. The grid structure 170 may include a conductive pattern and/or a low refractive pattern. The grid structure 170 may include a light shielding pattern configured to prevent a color blend. For example, the grid structure 170 may include a metal such as titanium, tantalum, tungsten, etc., a polymer having a refractive index of about 1.1 to about 1.3, etc.

In some example embodiments, a planarizing layer (not shown) may be interposed between the second surface S2 of the semiconductor substrate 100 and the grid structure 170. The planarizing layer may include a transparent insulation material.

The color filter 180 may be formed in each of the pixels PX divided by the grid structure 170. The color filter 180 may include a red filter, a green filter, a blue filter, etc. The color filter 180 may include a magenta filter, a cyan filter, a yellow filter, etc. Although not depicted in drawings, a protection layer may be interposed between the color filter 180 and the grid structure 170. The protection layer having a conformal thickness may be formed at the resultant on the second surface S2 of the semiconductor structure 100 with the grid structure 170.

The micro-lens 190 may be arranged on the color filter 180. For example, the micro-lens 190 may include a convex lens having a curvature. The micro-lens 190 may include a light transmissive resin.

The micro-lens 190 may correspond to the at least one pixel PX. The micro-lens 190 and the color filter 180 may be arranged on the second surface S2 of the semiconductor substrate 100 to cover the first and second sub-pixels SP1 and SP2.

According to example embodiments, the transfer transistor may be arranged at the central region of the photodiode so that the migration distances of the charges generated from the photodiode may be greatly decreased to improve the charge transfer efficiency of the image sensing device.

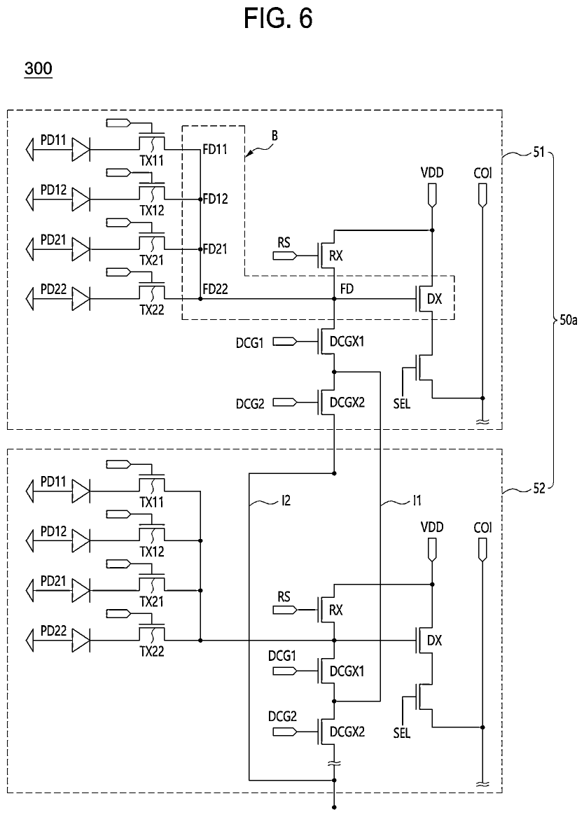

FIG. 6 is a block diagram illustrating an image sensing device based on example embodiments.

Referring to FIG. 6, an image sensing device 300 of example embodiments may include a plurality of photodiodes and a plurality of pixel circuits 50a. The pixel circuits 50a may be variably connected to the photodiodes to obtain a triple conversion gain (TCG). In some example embodiments, FIG. 6 may show first and second pixel circuits 51 and 52 integrated in each of four photodiode regions. For example, the first and second pixel circuits 51 and 52 may be arranged under a color filter having a single color. Further, the first and second pixel circuits 51 and 52 may have substantially the same configuration. Thus, only the configuration of the first pixel circuit 51 may be explained herein.

The first pixel circuit 51 may be connected to first photodiodes PD11 and PD21 and second photodiodes PD12 and PD22. The first pixel circuit 51 may include first transfer transistors TX11 and TX21, second transfer transistors TX12 and TX22, a driving transistor DX, a selection transistor SX, a reset transistor RX and first and second dual conversion gain transistors DCGX1 and DCGX2.

The first transfer transistors TX11 and TX21 and the second transfer transistors TX12 and TX22 may be connected to the first photodiodes PD11 and PD21 and the second photodiodes PD12 and PD22, respectively. The first transfer transistors TX11 and TX21 and the second transfer transistors TX12 and TX22 may include first and second floating diffusion regions FD11, FD21, FD21 and FD22.

The driving transistor DX may be a source follower turned-on based on a quantity of charges accumulated in the floating diffusion region FD. A reference numeral FD in FIG. 6 may indicate the floating diffusion region corresponding to an integral connection node of the first and second floating diffusion regions FD11, FD21, FD12 and FD22. The selection transistor SX and the reset transistor RX may be substantially the same as the selection transistor SX and the reset transistor RX in FIG. 3. Thus, any further illustrations with respect to the selection transistor SX and the reset transistor RX may be omitted herein for brevity.

The first and second dual conversion gain transistors DCGX1 and the DCGX2 may be electrically connected with the floating diffusion region FD to perform the TCG operation. The TCG technology may be used for manufacturing the image sensing device 300 having a high conversion gain, a middle conversion gain and a low conversion gain. The first dual conversion gain transistor DCGX1 may be electrically connected between the floating diffusion region FD and the second dual conversion gain transistor DCGX2. The first dual conversion gain transistor DCGX1 may change a capacitance of the floating diffusion region FD based on a first conversion gain gate signal DCGS1. A drain of the first dual conversion gain transistor DCGX1 in the first pixel circuit 51 may be electrically connected with a drain of the first dual conversion gain transistor DCGX1 in the second pixel circuit 52 through a first interconnection I1.

The second dual conversion gain transistor DCGX2 may be electrically connected with a source of the first dual conversion gain transistor DCGX1 and a source of the second dual conversion gain transistor DCGX2 in a pixel circuit corresponding to a color filter having a different color through a second interconnection I2.

In some example embodiments, when the first dual conversion gain gate signal DCGS1 and a second dual conversion gain gate signal DCGS2 may be disabled, the driving transistor DX may be turned-on based on the charge quantity of the photodiode connected to the enabled transfer transistor so that the image sensing device 300 may obtain the high conversion gain.

When the first dual conversion gain gate signal DCGS1 may be enabled and the second dual conversion gain gate signal DCGS2 may be disabled, the floating diffusion region FD of the first pixel circuit 51 and the floating diffusion region FD of the second pixel circuit 52 may be shared with each other so that the image sensing device 300 may obtain the middle conversion gain.

When the first dual conversion gain gate signal DCGS1 and the second dual conversion gain gate signal DCGS2 may be enabled, the floating diffusion region FD of the first pixel circuit 51 and the floating diffusion region of the pixel circuit corresponding to the other color filter may be shared with each other so that the image sensing device 300 may obtain a high dynamic range.

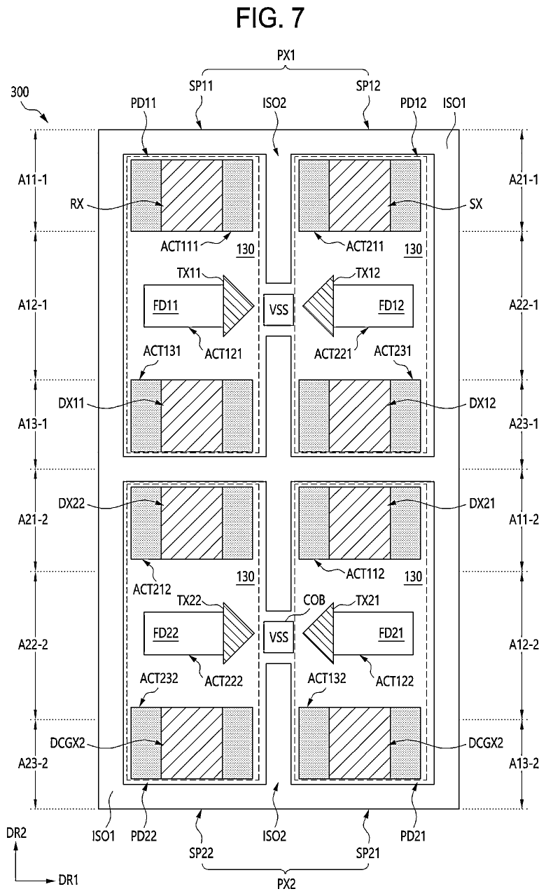

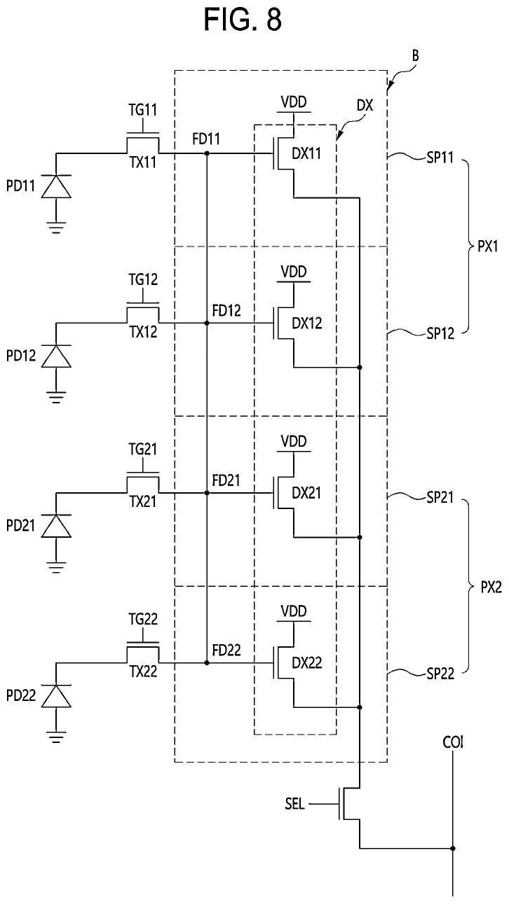

FIG. 7 is a plan view illustrating the image sensing device including a first pixel circuit in FIG. 6 and FIG. 8 is a circuit diagram illustrating a portion “D in FIG. 6.

Referring to FIG. 7, the image sensing device 300 may include a plurality of pixels. A first pixel circuit 51 configured to obtain the TCG may include four transistors such as the reset transistor RX, the selection transistor SX and the first and second dual conversion gain transistors DCGX1 and DCGX2 except for the transfer transistors TX11, TX12, TX21 and TX22 and the driving transistor DX. Thus, the first pixel circuit 51 may be integrated in two pixels (1×2) including first and second sub-pixels.

That is, the image sensing device 300 may include the first pixel PX1 and the second pixel PX2. The first and second pixels PX1 and PX2 may be divided by the first pixel isolation layer ISO1. Each of the first and second pixels PX1 and PX2 may include two sub-pixels SP11, SP12, SP21 and SP22. For example, the first and second sub-pixels SP11, SP12, SP21 and SP22 may be isolated by the second pixel isolation layer ISO2.

First and second photodiodes PD11, PD12, PD21 and PD22 may be formed on all regions of a first conductive type semiconductor substrate divided into the first and second sub-pixels SP11, SP12, SP21 and SP22. The first and second photodiodes PD11, PD12, PD21 and PD22 may include a second conductive type impurity region.

A device isolation layer 130 may be formed in the first and second sub-pixels SP11, SP21, SP12 and SP22 with the first and second photodiodes PD11, PD12, PD21 and PD22 to define a plurality of active regions.

In some example embodiments, the active regions may include first active regions ACT111, ACT211, ACT112 and ACT212, second active regions ACT121, ACT221, ACT122 and ACT222 and third active regions ACT131, ACT231, ACT132 and ACT232 formed in the first and second sub-pixels SP11, SP21, SP12 and SP22.

Regions where the first active regions ACT111, ACT211, ACT112 and ACT212 may be defined as upper regions A11-1, A21-2, A11-2 and A21-2 of the sub-pixels SP11, SP21, SP12 and SP22. Regions where the second active regions ACT121, ACT221, ACT122 and ACT222 may be defined as central regions A12-1, A22-2, A12-2 and A21-2 of the sub-pixels SP11, SP21, SP12 and SP22. Regions where the third active regions ACT131, ACT231, ACT132 and ACT232 may be defined as lower regions A12-1, A22-1, A12-2 and A22-2 of the sub-pixels SP11, SP21, SP12 and SP22. The upper regions A11-1, A21-1, A11-2 and A21-2, the central regions A12-1, A22-1, A12-2 and A22-2 and the lower regions A12-1, A22-2, A12-2 and A22-2 may be positioned on a same plane.

In some example embodiments, the reset transistor RX may be integrated in the first active region ACT111 of the first sub-pixel SP11 in the first pixel PX1. The first transfer transistor TX11 and the first floating diffusion region FD11 may be integrated in the second active region ACT121 of the first sub-pixel SP11 in the first pixel PX1. The first driving transistor DX11 may be integrated in the third active region ACT131 of the first sub-pixel SP11 in the first pixel PX1.

The selection transistor SX may be integrated in the first active region ACT211 of the second sub-pixel SP12 in the first pixel PX1. The second transfer transistor TX12 and the second floating diffusion region FD12 may be integrated in the second active region ACT221 of the second sub-pixel SP12 in the first pixel PX1. The second driving transistor DX12 may be integrated in the third active region ACT231 of the second sub-pixel SP12 in the first pixel PX1.

The first driving transistor DX21 may be integrated in the first active region ACT112 of the first sub-pixel SP21 in the second pixel PX2. The first transfer transistor TX21 and the first floating diffusion region FD21 may be integrated in the second active region ACT122 of the first sub-pixel SP21 in the second pixel PX2. The first dual conversion gain transistor DCGX1 may be integrated in the third active region ACT132 of the first sub-pixel SP21 in the second pixel PX2.

The second driving transistor DX22 may be integrated in the first active region ACT212 of the second sub-pixel SP22 in the second pixel PX2. The second transfer transistor TX22 and the second floating diffusion region FD22 may be integrated in the second active region ACT 222 of the second sub-pixel SP22 in the second pixel PX2. The third dual conversion gain transistor DCGX3 may be integrated in the third active region ACT132 of the second sub-pixel SP22 in the second pixel PX2.

The reset transistor RX, the selection transistor SX and the first and second driving transistors DX11, DX21, DX12 and DX22 may include NMOS transistors having the planar gate in FIG. 5B.

Referring to FIG. 5A, the first and second transfer transistors TX11, TX21, TX12 and TX22 may have a recessed gate structure. Further, sources of the first and second transfer transistors TX11, TX21, TX12 and TX22 may include first and second photodiodes PD11, PD21, PD12 and PD22. Drains of the first and second transfer transistors TX11, TX21, TX12 and TX22 ma include the first and second floating diffusion regions FD11, FD21, FD12 and FD22. The first transfer transistors TX11 and TX21 may be symmetrical with the second transfer transistors TX12 and TX22 with respect to the second pixel isolation layer ISO2.

Referring to FIG. 7, the driving transistor DX11, DX21, DX12 and DX22 may be arranged in the sub-pixels SP11, SP21, SP12 and SP22, respectively. Thus, the driving transistor DX in FIG. 6 may be fingered into the first and second driving transistors DX11, DX21, DX12 and DX22 connected to the first and second floating diffusion regions FD11, FD21, FD12 and FD22. Further, a current gain and a drive force of the first and second driving transistors DX11, DX21, DX12 and DX22 may be improved based on a fingering principle of a transistor.

Additionally, the first and second driving transistors DX11, DX21, DX12 and DX22, which may receive voltages from the floating diffusion regions FD11, FD21, FD12 and FD22 based on the charge quantity, may be arranged in the sub-pixels SP11, SP21, SP12 and SP22. The first and second driving transistors DX11, DX21, DX12 and DX22 may be adjacent to the floating diffusion regions FD11, FD21, FD12 and FD22. Thus, the charges accumulated in the first and second floating diffusion regions FD11, FD21, FD12 and FD22 may be transferred to the gates of the first and second driving transistors DX11, DX21, DX12 and DX22 through a relatively short conductive path to improve the charge transfer characteristic.

In some example embodiments, the first and second driving transistors DX11 and DX12 in the first pixel PX1 may be positioned in the lower regions A13-1 and A23-1. The first and second driving transistors DX21 and DX22 in the second pixel PX2 may be arranged in the upper regions A11-2 and the A21-2. Thus, layout efficiency such as a length of a wiring may be improved.

When the first and second sub-pixels SP11, SP21, SP12 and SP22 may have substantially the same size, the first and second driving transistors DX11, DX21, DX12 and DX22 may have substantially the same drive force, but not limited thereto. Alternatively, the first and second driving transistors DX11, DX21, DX12 and DX22 may be variously designed based on sizes of the first and second sub-pixels SP11, SP21, SP12 and SP22.

Further, positions of the reset transistor RX, the selection transistor SX and the first and second dual conversion gain transistors DCGX1 and DCGX2 may be variously changed based on the layout efficiency.

Recently, in order to improve a noise of an image sensing device, one transfer transistor and one pixel transistor may be integrated in one sub-pixel. In order to secure an area of the pixel transistor, the transfer transistor may be arranged at a corner of the sub-pixel. When the transfer transistor may be arranged at the corner of the sub-pixel, migration lengths of the charges generated from the photodiode may be elongated or may not be uniform so that the charge transfer characteristic may be decreased.

The transfer transistors TX11, TX21, TX12 and TX22 including the floating diffusion regions FD11, FD21, FD12 and FD22 may be arranged in the central regions A12-1, A22-1, A12-2 and A22-2 including the center points of the sub-pixels SP11, SP21, SP12 and SP22, i.e., the central regions of the photodiodes PD11, PD21, PD12 and PD22.

Therefore, the distances between the photodiodes PD11, PD21, PD12 and PD22 and the transfer transistors TX11, TX21, TX12 and TX22 may be decreased. Further, the distances between the photodiodes PD11, PD21, PD12 and PD22 and the transfer transistors TX11, TX21, TX12 and TX22 may be uniform to improve the charge transfer characteristic. By improving the charge transfer characteristics, a great amount of the charges may be transferred by applying a low power voltage to reduce a lag. As a result, the Gm characteristic and the noise may be improved and the conversion gain may be secured by improving the charge transfer characteristic.

Further, the transfer transistors TX11, TX21, TX12 and TX22 may be arranged in the central regions A12-1, A22-1, A12-2 and A22-2 of the sub-pixels SP11, SP21, SP12 and SP22 so that the spaces where the pixel transistors may be integrated may be formed in the upper regions A11-1, A21-1, A11-2 and A21-2 and the lower regions A13-1, A23-1, A13-2 and A23-2 of each of the sub-pixels SP11, SP21, SP12 and SP22. Thus, the TCG pixel circuit 51 requiring at least five pixel transistors may be formed using the two pixels (1×2) including the four sub-pixels. As a result, the pixel circuit 51 may be formed using the pixels less than the pixels of a conventional pixel circuit including (2×2) pixels to secure the conversion gain.

In some example embodiments, the space where the pixel transistors may be integrated may be formed in the upper regions A11-1, A21-1, A11-2 and A21-2 and the lower regions A13-1, A23-1, A13-2 and A23-2 of each of the sub-pixels SP11, SP21, SP12 and SP22 so that the driving transistors DX1, DX2, DX3 and DX4 may be arranged in the sub-pixels SP11, SP21, SP12 and SP22 in the fingering shape to improve the output characteristics of the driving transistors DX1, DX2, DX3 and DX4.

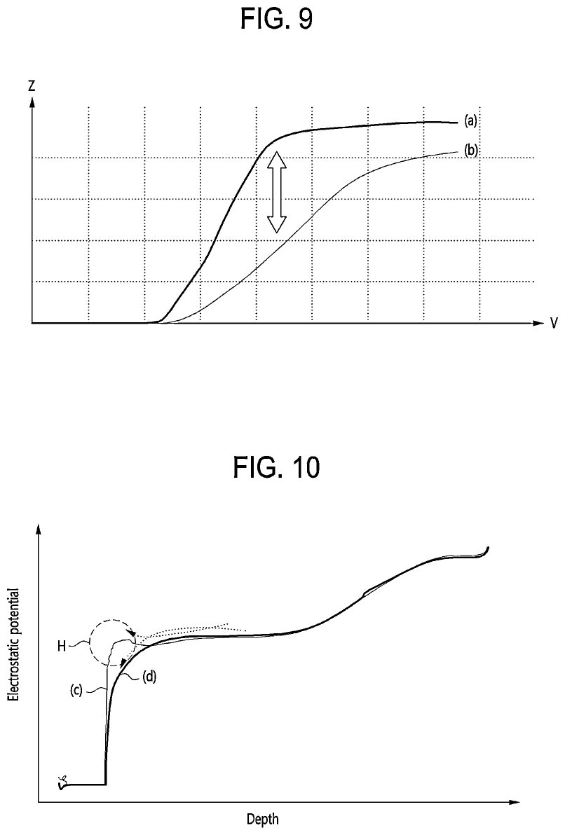

FIG. 9 is a graph showing characteristics of a driving transistor based on example embodiments.

In FIG. 9, a condition (a) may represent a current-voltage characteristic of the driving transistor fingered by the sub-pixel and a condition (b) may represent a current-voltage characteristic of the driving transistor occupying a great part of regions divided into the sub-pixels. When the driving transistors may be arranged in each of the sub-pixels in the condition (a), it can be noted that the output current characteristic at a same voltage may be improved by the fingering effect.

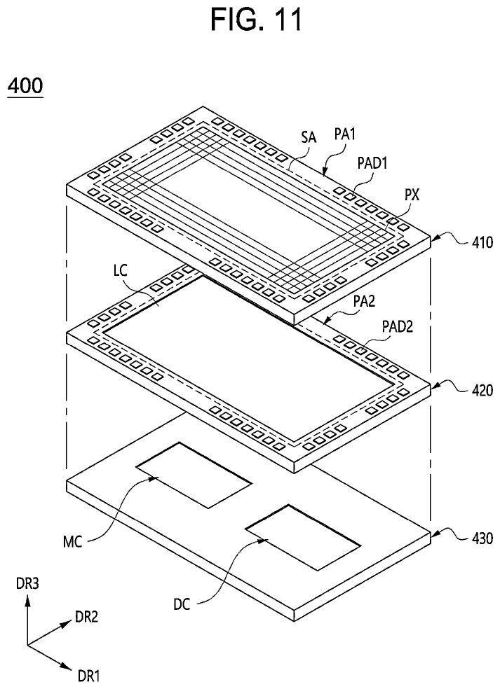

FIG. 10 is a graph showing charge flows between a photodiode and a floating diffusion region based on example embodiments.

In FIG. 10, a line (c) may represent a charge flow when the floating diffusion region may be arranged at the corner of the photodiode and a line (d) may represent a charge flow when the floating diffusion region may be arranged at the central region of the photodiode.

As shown in FIG. 10, when the floating diffusion region may be arranged at the corner of the photodiode in the condition (c), d distance between the central region of the photodiode on which the charges may be concentrated and the floating diffusion region may be increased. When the charge transfer path between the photodiode and the floating diffusion region may be increased, an undesired potential hump H may be generated in the charge transfer path to hinder the charge transfer.

In contrast, when the floating diffusion region may be arranged at the central region of the photodiode in the condition (d), the distance between the photodiode and the central region may be decreased. Thus, materials causing an additional potential difference may be reduced. As a result, it can be noted that the charges may be transferred from the photodiode to the floating diffusion region along a gentle curvature without the hump.

FIG. 11 is a perspective view illustrating an image sensing module based on example embodiments.

Referring to FIG. 11, an image sensing module 400 of example embodiments may include an image sensing layer 410, a first control layer 420 and a second control layer 430. The first control layer 420 may be arranged under the image sensing layer 410. The second control layer 430 may be arranged under the first control layer 420.

The image sensing layer 410 may include the pixel array 11 in FIG. 1 and a first pad region PA1. As mentioned above, the pixel array 11 may include the pixels PX. As shown in FIGS. 3 to 8, at least one of the pixels PX may include the two sub-pixels. Each of the sub-pixels may include the floating diffusion region and the driving transistor. The floating diffusion region may accumulate the charges converted by the photodiode. The driving transistor may be positioned adjacent to the floating diffusion region. The two pixels may be shared with each other to form the pixel circuit configured to process the charges in FIGS. 3 to 6. In some example embodiments, the pixel array 11 may include a light receiving surface, i.e., a backside of a semiconductor substrate. The light receiving surface may be oriented toward an outer direction. The first pad region PA1 may be arranged at an edge region of a sensing region SA. The first pad region PA1 may include a plurality of first pads PAD1. The first pads PAD1 may receive various signals from the first control layer 420. The first pads PAD1 may transmit the signals to the pixels PX.

The first control layer 420 may include a plurality of control logic circuits LC and a second pad region PA2. The control logic circuit LC may include the row driver 12, the readout circuit RO and the timing controller TC in FIG. 1. The second pad region PA2 may be positioned at an edge region of the control logic circuit LC. The second pad region PA2 may include a plurality of second pads PAD2. The second pads PAD2 may be electrically connected with the first pads PAD1. The control logic circuit LC may generate various signals for driving the pixel circuit. The control logic circuit LC may provide the second pads PAD2 with the signals. The first pads PAD1 may receive the pixel signal provided from the pixel circuits 50 or 50a. The first pads PAD1 may provide the second pads PAD2 with the pixel signal. The control logic circuit LC may process the pixel signal received through the second pads PAD2 to generate image data. The control logic circuit LC may process the image data to form an image.

The first image sensing layer 410 and the first control layer 420 may be boned to each other on a wafer level. In some example embodiments, a first wafer including the image sensing layer 410 and a second wafer including the first control layer 420 may be hybrid-bonded to each other. The bonded first and second wafers may be cut to form a package.

The second control layer 430 may include a memory chip MC and a dummy chip DC. In some example embodiments, the memory chip MC may include a DRAM chip, an SRAM chip, etc. The memory chip MC may store information for providing the image sensing layer 410 with an automatic focusing function. The second control layer 430 may be electrically connected with the first control layer 420. The second control layer 430 may be connected with the first control layer 420, which may be boned to the image sensing layer 410, through a bump.

Alternatively, the first control layer 420 may be integrated in a wafer where the image sensing layer 410 may be integrated.

Further, the first control layer 420 may include an additional chip. The additional chip may be mounted on a package substrate on which the second control layer 430 may be mounted.

Furthermore, the image sensing layer 410, the first control layer 420 and the second control layer 430 may be packaged to form one package.

Only limited examples of implementations or embodiments of the disclosed technology are described or illustrated. Variations and enhancements for the disclosed implementations or embodiments and other implementations or embodiments are possible based on what is disclosed and illustrated in this patent document.

What is claimed is:

1. An image sensing device comprising:
a plurality of pixels, each of the plurality of pixels including at least one sub-pixel,
wherein the at least one sub-pixel comprises:
a photodetector to convert received light into electrical charge;
a transfer transistor configured to transfer the electrical charge, which is generated from the photodetector, to a floating diffusion region; and
a plurality of pixel transistors configured to generate a pixel signal based on the electrical charge provided from the transfer transistor,
wherein the transfer transistor is positioned closer to a center of the sub-pixel than each of the plurality of the pixel transistors.

2. The image sensing device of claim 1,
wherein the sub-pixel comprises: a central region including the center; a first region arranged closer to a first edge of the sub-pixel than the central region on a plane; and a second region arranged closer to a second edge of the sub-pixel than the central region on the plane, wherein the second edge is on an opposite side of the first edge based on the center region,
wherein the transfer transistor is arranged in the central region.

3. The image sensing device of claim 2, wherein the plurality of the pixel transistors comprises:
a first pixel transistor arranged in the first region; and
a second pixel transistor arranged in the second region.

4. The image sensing device of claim 3,
wherein the first pixel transistor comprises at least one of a reset transistor, a selection transistor, a first dual conversion gain transistor, and a second dual conversion gain transistor, and
wherein the second pixel transistor comprises a driving transistor.

5. The image sensing device of claim 1, wherein at least one of the pixels comprises a first sub-pixel and a second sub-pixel,
wherein the image sensing device further comprises:
a first pixel isolation layer configured to isolate the pixels from each other; and
a second pixel isolation layer formed in a region surrounded by the first pixel isolation layer to define areas corresponding to the first sub-pixel and the second sub-pixel.

6. The image sensing device of claim 5, wherein the transfer transistor and the floating diffusion region in the first sub-pixel, and the transfer transistor and the floating diffusion region in the second sub-pixel are arranged symmetrically with each other with respect to the second pixel isolation layer.

7. The image sensing device of claim 3, further comprising a device isolation layer configured to define a first active region where the first pixel transistor in the first region is disposed, a second active region where the transfer transistor and the floating diffusion region in the central region are disposed, and a third active region where the second pixel transistor in the second region is disposed.

8. The image sensing device of claim 7, wherein the floating diffusion region in the first sub-pixel and the floating diffusion region in the second sub-pixel are arranged to face each other with a gate of a driving transistor and the device isolation layer interposed between the floating diffusion regions.

9. The image sensing device of claim 7, wherein the photodetector includes a photodiode.

10. An image sensing device comprising:
a first sub-pixel group including a first sub-pixel and a second sub-pixel, the first and second sub-pixels of the sub-pixel group arranged side by side in a first direction; and
a second sub-pixel group arranged side by side with the first sub-pixel group along a second direction substantially perpendicular to the first direction, the second sub-pixel group including a first sub-pixel and a second sub-pixel, the first and second sub-pixels of the second sub-pixel group being arranged side by side in the first direction,
wherein each of the first sub-pixels and the second sub-pixels of the first and second sub-pixel groups comprises:
a first active region formed in a first region of each of the first and second sub-pixels;
a second active region formed in a central region of each of the first and second sub-pixels;
a third active region formed in a second region of each of the first and second sub-pixels, wherein the second region is on an opposite side of the central region from the first region;
a photodiode arranged to at least partially overlap the first to third active regions;
a first pixel transistor disposed in at least one of the first active region and the third active region;
a second pixel transistor disposed in a remaining one of the first active region and the third active region; and
a transfer transistor including a floating diffusion region disposed in the second active region.

11. The image sensing device of claim 10,
wherein at least one of the first pixel transistor and the second pixel transistor comprises one of a reset transistor, a selection transistor, a first dual conversion gain transistor, or a second dual conversion gain transistor, and
wherein a remaining one of the first pixel transistor and the second pixel transistor comprises a driving transistor.

12. The image sensing device of claim 10, further comprising:
a first pixel isolation layer configured to isolate the first sub-pixel group and the second sub-pixel group from each other;
a second pixel isolation layer formed in a region divided by the first pixel isolation layer to define the first sub-pixel and the second sub-pixel; and
a device isolation layer formed in the first sub-pixel and the second sub-pixel to define the first active region, the second active region and the third active region.

13. The image sensing device of claim 12, wherein the transfer transistors region in the first sub-pixel and the second sub-pixel are arranged symmetrically with each other with respect to the second pixel isolation layer.

14. The image sensing device of claim 12,
wherein driving transistors in the first and second sub-pixel of the first sub-pixel group are arranged in the third active region, and
wherein the driving transistors in the first and second sub-pixels of the second sub-pixel group are arranged in the first active region.

15. An image sensing device comprising:
a semiconductor substrate having a first conductive type, the semiconductor substrate including a front side and a back side;
a pixel isolation layer formed in the semiconductor substrate to define a first sub-pixel group and a second sub-pixel group, each of the first and second sub-pixel groups including first and second sub-pixels;
a photodiode formed in the semiconductor substrate defined by the first and second sub-pixels;
a device isolation layer formed on the front side of the semiconductor substrate defined by the first and second sub-pixels of the first and second sub-pixel groups to define a first active region, a second active region and a third active region;
a pixel transistor arranged in at least one of the first active region and the third active region; and
a transfer transistor including a floating diffusion region in the second active region,
wherein the second active region is positioned between the first active region and the third active region.

16. The image sensing device of claim 15,
wherein a transfer gate of the transfer transistor is arranged on the second active region, and
wherein the floating diffusion region including second conductive type impurities is formed in the second active region exposed by the transfer gate.

17. The image sensing device of claim 15, wherein the pixel transistor comprises a reset transistor, a selection transistor, a first dual conversion gain transistor, and a second dual conversion gain transistor.

18. The image sensing device of claim 15, further comprising:
a color filter arranged on the back side of the semiconductor substrate; and
a micro-lens arranged on the color filter.

19. The image sensing device of claim 18, wherein the color filter and the micro-lens are arranged at a position corresponding to the first sub-pixel group.

20. The image sensing device of claim 18, wherein the color filter and the micro-lens is arranged at a position configured to cover the first sub-pixel group and the second sub-pixel group.
